(19) United States
(12) Patent Application Publication
(10) Pub. No.: US 2005/0156512 A1
(43) Pub. Date: Jul. 21, 2005

(54) Electroluminescent devices with at least one electrode having apertures and methods of using such devices

(76) Inventors: Vadim Savvateev, St. Paul, MN (US); Martin B. Wolk, Woodbury, MN (US); William A. Tolbert, Woodbury, MN (US)

Correspondence Address: 3M INNOVATIVE PROPERTIES COMPANY, PO BOX 33427, ST. PAUL, MN, 55133-3427, US

(21) Appl. No.: 11/015,709

(22) Filed: Dec. 17, 2004

Related U.S. Application Data
(60) Provisional application No. 60/533,475, filed on Dec. 30, 2003.

(51) Int. Cl. H05B 33/00; H05B 33/02

(52) U.S. Cl. 313/503; 313/506; 313/500

(57) ABSTRACT

An electroluminescent device that includes one or more electrodes having apertures through which light is emitted is disclosed. A method of using such device is also disclosed.

### CROSS REFERENCE TO RELATED APPLICATION

This application claims priority to U.S. Provisional Patent Application No. 60/533,475, filed Dec. 30, 2003.

### BACKGROUND

Light emitting devices, such as organic or inorganic electroluminescent (OEL) devices, are useful in a variety of display, lighting, and other applications. Generally, these light emitting devices include one or more devices layers, including at least one light emitting layer, disposed between two electrodes (an anode and a cathode). A voltage drop or current is provided between the two electrodes causing a light emitting material, which can be organic or inorganic, in the light emitting layer to luminesce. Typically, one or both of the electrodes is transparent so that light can be transmitted through the electrode to a viewer or other light receiver.

One popular material for forming transparent electrodes is indium tin oxide (ITO). This material, however, has relatively low conductivity for an electrode material and can be brittle. In addition, a buffer layer is often disposed between the ITO electrode and the device layer(s) because electrode material diffuses over time from the ITO into the surrounding layers. This can alter the properties of the device, including the electrical properties, and reduce device lifetime.

### SUMMARY

Generally, the present disclosure relates to electroluminescent devices and methods of using such devices. The present disclosure also relates to electroluminescent devices with one or more electrodes having apertures through which light is emitted and methods of using such devices.

In one aspect, the present disclosure provides an electroluminescent device that includes a first electrode defining a plurality of apertures through the first electrode. The device further includes a second electrode defining a plurality of apertures through the second electrode, where the second electrode is opaque. The device further includes a light emitting layer between the apertures in the first electrode and the apertures in the second electrode. The electroluminescent device is configured and arranged to emit light through the apertures in the first electrode and the second electrode when light is generated by the light emitting layer.

In another aspect, the present disclosure provides an electroluminescent device that includes a substrate, and a first electrode disposed on the substrate, where the first electrode defines a plurality of apertures through the first electrode. The device further includes a light emitting layer disposed over the first electrode, and a second electrode disposed over the light emitting layer. The electroluminescent device is configured and arranged to emit light through the apertures in the first electrode when light is generated by the light emitting layer.

In another aspect, the present disclosure provides a method of emitting light, including providing an electroluminescent device that includes a first electrode defining a plurality of apertures through the first electrode. The device further includes a second electrode defining a plurality of apertures through the second electrode, and a substantially flat light emitting layer extending laterally between the first electrode and second electrode and between the apertures in the first electrode and the apertures in the second electrode. The method further includes applying an electrical signal to the first and second electrodes to cause the light emitting layer to emit light through the apertures in the first electrode and the apertures in the second electrode.

In another aspect, the present disclosure provides an electroluminescent device that includes a first electrode, and a second electrode defining a plurality of apertures through the second electrode, where each aperture includes an edge. The device further includes a light emitting layer between the first electrode and the apertures in the second electrode. The electroluminescent device is configured and arranged to emit light through the apertures in the second electrode when light is generated by the light emitting layer. The electroluminescent device is also configured and arranged to provide an increased electric field strength proximate the edge of at least one aperture of the plurality of apertures.

The above Summary of the present disclosure is not intended to describe each disclosed embodiment or every implementation of the present disclosure. The Figures and the Detailed Description that follow more particularly exemplify illustrative embodiments.

### BRIEF DESCRIPTION OF THE DRAWINGS

FIG. 1 is a schematic cross-sectional view of an embodiment of an electroluminescent device.

FIG. 2 is a schematic top plan view of one possible structure of the electroluminescent device of FIG. 1.

FIG. 3 is a schematic top plan view of another embodiment of an electroluminescent device.

FIG. 4 is a schematic cross-sectional view of another embodiment of an electroluminescent device.

FIG. 5 is a schematic cross-sectional view of another embodiment of an electroluminescent device.

FIG. 6 is a schematic cross-sectional view of another embodiment of an electroluminescent device.

FIG. 7 is a schematic cross-sectional view of an embodiment of an electroluminescent device disposed on a cylindrical substrate.

FIG. 8 is a schematic cross-sectional view of another embodiment of an electroluminescent device disposed on a cylindrical substrate.

FIG. 9 is a schematic cross-sectional view of another embodiment of an electroluminescent device disposed on a cylindrical substrate.

FIG. 10 is a schematic top plan view of one possible structure of the electroluminescent device of FIG. 1.

### DETAILED DESCRIPTION

In the following detailed description of illustrative embodiments, reference is made to the accompanying drawings that form a part hereof, and in which are shown, by way of illustration, specific embodiments in which the disclosure may be practiced. It is to be understood that other embodiments may be utilized and structural changes may be made without departing from the scope of the present disclosure.

The present disclosure is believed to be applicable to electroluminescent devices and methods of using such electroluminescent devices. In particular, the present disclosure is directed to electroluminescent devices having at least one electrode with apertures defined by the electrode through which light is emitted and methods of using such devices. In at least some embodiments, the electrode with apertures is not transparent and can be opaque. While the present disclosure is not so limited, an appreciation of various aspects of the disclosure will be gained through a discussion of the embodiments provided herein.

Electroluminescent devices can include organic or inorganic light emitters or combinations of both types of light emitters. An organic electroluminescent (OEL) display or device refers to an electroluminescent display or device that includes at least one organic emissive material, whether that emissive material is a small molecule (SM) emitter (e.g., nonpolymeric emitter), a SM doped polymer, a light emitting polymer (LEP), a doped LEP, a blended LEP, or another organic emissive material whether provided alone or in combination with any other organic or inorganic materials that are functional or non-functional in the OEL display or devices. Inorganic light emissive materials include phosphors, semiconducting nanocrystals (e.g., quantum dots), etc.

Generally, the electroluminescent devices have one or mote device layers, including at least one light emitting layer, disposed between two electrodes (an anode and a cathode). A voltage drop or current is provided between the two electrodes causing the light emitter to luminesce. In at least some embodiments, both electrodes are non-transparent and can be opaque. At least one of the electrodes includes apertures through the electrode to allow light to be transmitted through the apertures to a viewer or other light receiver.

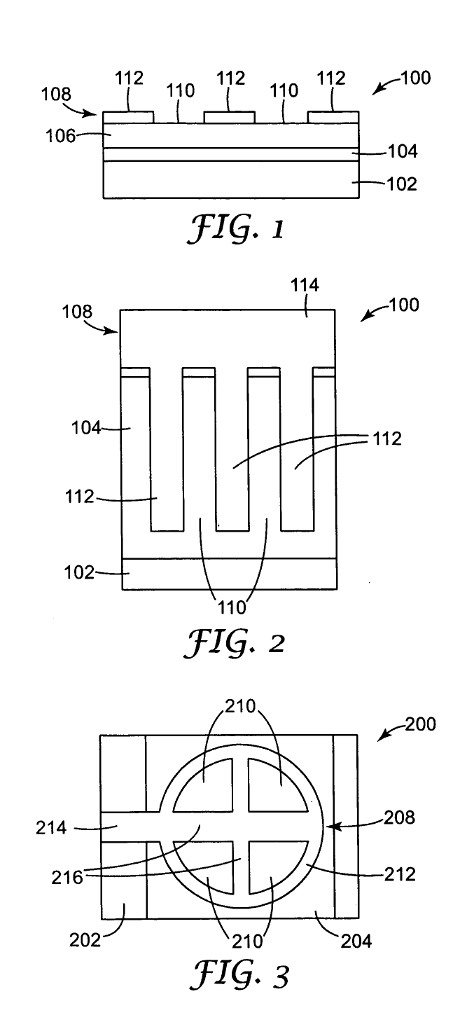

FIG. 1 illustrates an embodiment of an electroluminescent device 100 of the present disclosure. The electroluminescent device 100 includes a substrate 102, first electrode 104, one or more device layers 106 (including a light emitting layer), and a second electrode 108. The first electrode 104 can be the anode and the second electrode 108 can be the cathode or the first electrode 104 can be the cathode and the second electrode 108 can be the anode. In this embodiment, the second electrode 108 is patterned to include one or more apertures 110 through the second electrode 108.

FIG. 2 illustrates a top plan view of one embodiment of the device 100 of FIG. 1. FIG. 2 illustrates the second electrode 108 as a series of parallel strips 112 connecting to a common region 114 with the apertures 110 positioned between the strips 112. Although apertures 110 are illustrated as being positioned between the strips 112, other areas proximate the strips 112 may also allow light to be transmitted. It will be recognized that the electrode 108 can have shapes other than parallel strips connected to a common region. For example, the electrode may include a ring-shaped common region with electrode lines running into or out of (or both into and out of) the ring or the electrode may include a series of concentric rings with one or more lines connecting the rings. Other examples of possible electrode configurations are illustrated in the Figures discussed herein.

For example, FIG. 3 illustrates a device 200 that includes a substrate 202, a first electrode 204, and a second electrode 208. Though not shown, device 200 can include one or more device layers between the first electrode 204 and the second electrode 208 (e.g., one or more device layers 106 of FIG. 1). The second electrode 208 includes a ring 212 and crossed strips 216 connected to a common region 214. Apertures 210 are positioned within the ring 212 and between strips 216. Although apertures 210 are illustrated as being positioned within ring 212, other areas outside ring 212 may also allow light to be transmitted.

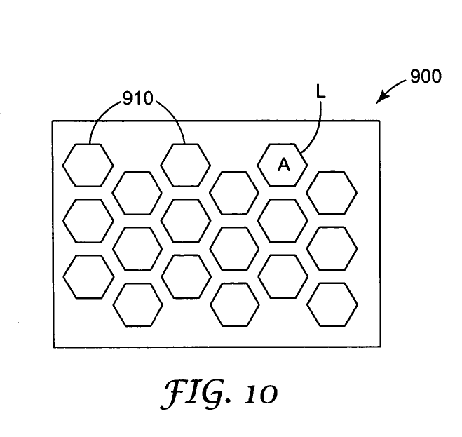

In general, the apertures can have any shape including regular shapes, such as square, rectangular, circular, oval, or polygonal shapes, or irregular shapes. For example, FIG. 10 is a schematic top plan view of an electrode 900 that includes apertures 910. The anode, the cathode, or both the anode and the cathode may take the form of the electrode 900 of FIG. 10. As shown in FIG. 10, each aperture 910 has a hexagonal shape having an opening area A and an edge length L. Although FIG. 10 depicts apertures 910 as having a hexagonal shape, apertures 910 may include any suitable shape.

In general, the apertures of the present disclosure can all have a common shape or size (or both a common shape and size) or the apertures can differ in shape or size or both shape and size. In some embodiments, the apertures can be divided into subsets of apertures having similar shape, size, or both shape and size. The configuration (e.g., pattern) of the apertures with respect to the electrode can be regular, irregular, or random. The pitch (e.g., spacing between apertures) of the apertures can be uniform or irregular. In some embodiments, the pitch or size (or both) of the apertures can vary according to a desired pattern. For example, the pitch or size (or both) can increase or decrease with distance from a particular point of the electroluminescent device. As another example, the pitch or size (or both) of the apertures can increase or decrease with distance from a particular side or from the center of the electroluminescent device. A variation (e.g., gradient) can be linear or non-linear (e.g., sinusoidal or exponential) and can include both increases or decreases in pitch or size (or both pitch and size). Variation in pitch, size, shape, configuration (e.g., pattern) or any combination of these can provide desired optical effects. These considerations regarding the pitch, size, shape, and configuration of the apertures and patterned electrode applies to any of the patterned electrodes disclosed in any of the embodiments described herein.

In some embodiments, light may be emitted proximate the edge of at least one aperture. As used herein, the term “edge emission” refers to light emission that occurs proximate the edges of the apertures of the anode and/or the cathode. While not wishing to be bound by any particular theory, edge emission may be caused by a large electric field and/or electric field gradient proximate the edges of the apertures.

Edge emission may be controlled using any suitable technique. For example, the edge length L for some or all of the apertures formed in an electrode may be increased, thereby increasing the net edge length for all of the apertures formed in the electrode. Increased edge length may be accomplished using any suitable technique. For example, apertures having polygonal shapes may be utilized to increase edge length. In some embodiments, the edges of the apertures may be roughened or textured to further increase edge length. Increasing the edge length of one or more apertures may increase the electric field strength and/or electric field gradient proximate the edges of the apertures, thereby increasing emission in regions of the light emitting layer that are proximate the edges of the apertures. One possible limitation to increasing edge length is the potential increase in device resistance due to the reduction in electrode material caused by increasing the size of the apertures formed in the electrode. Therefore, in an exemplary embodiment, the ratio of edge length L to opening area A for at least one aperture is increased to provide maximum edge length while removing minimal electrode material.

In some embodiments, light may be emitted proximate overlapping cross-sectional regions of the anode and cathode. As used herein, the term “area emission” refers to emission that occurs in overlapping regions of the anode and cathode. While not wishing to be bound by any particular theory, the light generated via area emission may bounce between the anode and cathode until it is emitted through one or more apertures. One possible limitation to area emission is that light generated in the middle of an overlapping region between electrodes may reflect off of one or both electrodes or other layers many times before escaping and thus may be partially or completely absorbed by the materials in the electroluminescent device. One technique that may be used to counteract this absorption is to reduce the overlapping areas of the anode and cathode such that a greater portion of light may be emitted prior to being absorbed by materials in the electroluminescent device.

In some embodiments, light may be emitted through apertures in the anode, cathode, or both the anode and cathode through a combination of edge emission and area emission. Further, in some embodiments, it may be preferred to decrease area emission and increase edge emission. One possible technique for achieving this is to increase the electric field strength and/or electric field gradient in regions of the light emitting layer proximate the edges of one or more electrode apertures. As described herein, the electric field strength and/or electric field gradient proximate the edge of an aperture may be increased by increasing the edge length L of the aperture. Increasing the edge length L of one or more apertures may be balanced with maintaining the conductivity of the electrode by removing as little electrode material as necessary to form the apertures.

Returning to FIG. 1, the first and second electrodes 104, 108 are typically formed using electrically conducting materials such as metals, alloys, metallic compounds, metal oxides, conductive ceramics, conductive dispersions, and conductive polymers. Examples of suitable materials include, for example, gold, platinum, palladium, aluminum, calcium, titanium, titanium nitride, indium tin oxide (ITO), fluorine tin oxide (FTO), and polyaniline. The first and second electrodes 104, 108 can be single layers of conducting materials or they can include multiple layers. For example, an anode or a cathode may include a layer of aluminum and a layer of gold, a layer of calcium and a layer of aluminum, a layer of aluminum and a layer of lithium fluoride, or a metal layer and a conductive organic layer.

In at least some embodiments, the second electrode 108 (having the apertures 110) is not transparent and can be opaque. The apertures 110 permit the use of a non-transparent second electrode 108 because the light generated by the device 100 can be emitted through the apertures 110. Thus, the second electrode 108 can be formed from a wider variety of materials than would be available if the second electrode 108 were required to be transparent to allow for emission of light through the second electrode 108. If the second electrode 108 is an anode, it may be preferred that its material or materials include gold, silver, or other materials with a work function that is suitable for the injection of positive charge into the organic layers of the device. These materials generally are more conductive than the typical transparent ITO electrode and are typically less brittle and more ductile. This can be particularly useful in flexible electroluminescent devices. In addition, because the electrode need not be transparent, a thicker electrode can be used, resulting in better conductivity for the electrode. Moreover, materials such as gold are much less likely than ITO to leach ions into neighboring layers. Under certain deposition conditions, metallic films can be made with near atomic smoothness. Smooth electrodes are beneficial in devices with ultrathin organic layers in order to avoid electrical shorts and to provide uniform electrical properties over the entire active area of the device. If the second electrode 108 is a cathode, it may be preferred that its material or materials include calcium, barium, aluminum, silver, gold, or other metals with a work function that is suitable for the injection of negative charge into the organic layers of the device.

Generally, the second electrode 108 is patterned to form the apertures 110 and electrode 108. Patterning can occur during formation of the electrode or after the electrode material has been deposited. Any known technique, suitable for the electrode material that is used, can be used to pattern the electrode, e.g., deposition through a mask to form the patterned electrode, photolithography, ablation, subablation, reactive ion etching, electrodeposition, thermal printing, microcontact printing, etc.

The substrate 102 of device 100 can be any substrate suitable for an electroluminescent device or display applications. For example, the substrate 102 can be made of glass, clear plastic, or other suitable material(s) that are substantially transparent to visible light. The substrate 102 can also be opaque to visible light, for example stainless steel, crystalline silicon, poly-silicon, or the like. In some instances, the first electrode 104 can be the substrate 102. Because materials used in at least some electroluminescent devices can be particularly susceptible to damage due to exposure to oxygen or water, a suitable substrate can be selected to provide an adequate environmental barrier, or is supplied with one or more layers, coatings, or laminates that provide an adequate environmental barrier.

The substrate 102 can also include any number of devices or components suitable in electroluminescent devices and displays, such as transistor arrays and other electronic devices; color filters, polarizers, wave plates, diffusers, and other optical devices; insulators, barrier ribs, black matrix, mask work, and other such components; and the like.

The one or more device layers 106 include a light emitting layer. Optionally, the one or more device layers 106 can include one or more additional layers such as, for example, a hole transport layer or layers, an electron transport layer or layers, a hole injection layer or layers, an electron injection layer or layers, a hole blocking layer or layers, an electron blocking layer or layers, a buffer layer or layers, or any combination thereof.

The light emitting layer typically contains at least one organic electroluminescent material. The electroluminescent material includes, but is not limited to, a fluorescent or phosphorescent material. The organic electroluminescent material can include, for example, a small molecule (SM) emitter (e.g., a non-polymeric emitter), a SM doped polymer, a light-emitting polymer (LEP), a doped LEP, or a blended LEP. The organic electroluminescent material can be provided alone or in combination with any other organic or inorganic materials that are functional or non-functional in an organic electroluminescent display or device.

In some embodiments, the organic electroluminescent material includes a light-emitting polymer (LEP). LEP materials are typically conjugated polymeric or oligomeric molecules that preferably have sufficient film-forming properties for solution processing. As used herein, “conjugated polymers or oligomeric molecules” refer to polymers or oligomers having a delocalized π-electron system along the polymer backbone. Such polymers or oligomers are semiconducting and can support positive and negative charge carriers along the polymeric or oligomeric chain.

Examples of classes of suitable LEP materials include poly(phenylenevinylenes), poly(para-phenylenes), polyfluorenes, other LEP materials now known or later developed, and co-polymers or blends thereof. Suitable LEPs can also be molecularly doped, dispersed with fluorescent dyes or photoluminescent materials, blended with active or non-active materials, dispersed with active or non-active materials, and the like. LEP materials can be formed into a light-emitting structure, for example, by casting a solvent solution of the LEP material on a substrate and evaporating the solvent to produce a polymeric film. Alternatively, LEP material can be formed in situ on a substrate by reaction of precursor species. Suitable methods of forming LEP layers are described in U.S. Pat. No. 5,408,109. Other techniques of forming a light-emitting structure from LEP materials include, but are not limited to, laser thermal patterning, inkjet printing, screen printing, thermal head printing, photolithographic patterning, and extrusion coating. The light-emitting structure can include a single layer or multiple layers of LEP material or other electroluminescent material.

In some embodiments, the organic electroluminescent material can include one or more small molecule emitters. SM electroluminescent materials include charge transporting, charge blocking, and semiconducting organic or organometallic compounds. Typically, SM materials can be vacuum deposited or coated from solution to form thin layers in a device. In practice, multiple layers of SM materials are typically used to produce efficient organic electroluminescent devices since a given material generally does not have both the desired charge transport and electroluminescent properties.

SM materials are generally non-polymeric organic or organometallic materials that can be used in OEL displays and devices as emitter materials, charge transport materials, dopants in emitter layers (e.g., to control the emitted color), charge transport layers, and the like. Commonly used SM materials include N,N′-bis(3-methylphenyl)-N,N′-diphenylbenzidine (TPD) and metal chelate compounds such as tris(8-hydroxyquinoline) aluminum (AlQ).

The one or more device layers 106 can optionally include a hole transport layer, an electron transport layer, a hole injection layer, an electron injection layer, a hole blocking layer, an electron blocking layer, a buffer layer, and the like. These and other layers and materials can be used to alter or tune the electronic properties and characteristics of the OEL devices. For example, such layers and materials can be used to achieve a desired current/voltage response, a desired device efficiency, a desired brightness, and the like. Additionally, photoluminescent materials can be present to convert the light emitted by the organic electroluminescent materials to another color. These optional layers can be positioned between the two electrodes and can be part of the light emitting layer or a separate layer.

For example, one or more device layers 106 can optionally include a hole transport layer between the light-emitting structure and one of the first or second electrodes 104, 108. The hole transport layer facilitates the injection of holes into the device and the migration of the holes towards the cathode. The hole transport layer can further act as a barrier for the passage of electrons to the anode. The hole transport layer can include, for example, a diamine derivative, such as N,N′-bis(3-methylphenyl)-N,N′-bis(phenyl)benzidine, N,N′-bis(3-naphthalen-2-yl)-N,N-bis(phenyl)benzidine, or a triarylamine derivative, such as 4,4′,4″-tris(N,N′-diphenylamino)triphenylamine, or 4,4′,4″-tris(N-3-methylphenyl-N-phenylamino)triphenylamine. Other examples include copper phthalocyanine and 1,3,5-tris(4-diphenylaminophenyl)benzenes.

The one or more device layers 106 can optionally include an electron transport layer between the light-emitting structure and one of the first or second electrodes 104, 108. The electron transport layer facilitates the injection of electrons and their migration towards the recombination zone. The electron transport layer can further act as a barrier for the passage of holes to the cathode. Preventing the holes from reaching the cathode and the electrons from reaching the anode will result in an electroluminescent device having higher efficiency. Suitable materials for the electron transport layer include, for example, tris(8-hydroxyquinolato) aluminum, 1,3-bis[5-(4-(1,1-dimethylethyl)phenyl)-1,3,4-oxadiazol-2-yl]benzene, 2-(biphenyl-4-yl)-5-(4-(1,1-dimethylethyl)phenyl)-1,3,4-oxadiazole, and other compounds as are known in the art.

The device 100 may be encapsulated. As used herein, the term “encapsulated” refers to having the (e.g., cathode) electrode surfaces free of exposure to oxygen and water. For embodiments where the devices are individually encapsulated, openings are made in the encapsulant layer to expose the electrical contacts. Depending on the composition of the various components, the useful lifetime of the electroluminescent device 100 can be extended by encapsulation. For example, some electrode materials and light-emitting structures deteriorate upon prolonged exposure to oxygen, moisture, or a combination thereof. Encapsulation reduces contact of the second electrode 108 or the light-emitting structure with oxygen or moisture.

The device 100 is typically encapsulated with a non-conductive material including, but is not limited to, ceramic material, glass material, polymeric material, and the like. Such non-conductive material is also suitable for use as the insulting layer. The typical thickness of the encapsulant layer is in the range of about 0.5 mils (0.012 mm) to about 2 mils (0.05 mm); whereas the thickness of the insulting layers is typically ranges from 0.01 microns to 5 microns. Suitable polymeric materials include thermoplastic or thermosetting homopolymers and thermoplastic or thermosetting copolymers. Examples of polymeric materials that can be used include polyurethanes, polyolefins, polyacrylates, polyesters, polyamides, epoxies, or combinations thereof. In some embodiments, the encapsulant polymeric material is an adhesive such as a hot melt adhesive or a pressure sensitive adhesive. The adhesive can be tacky or non-tacky at room temperature. The acidity of the polymeric material is preferably sufficiently low to avoid corrosion of the electrodes. The encapsulant material can include a desiccant such as, for example, CaO, BaO, SrO, and MgQ. The encapsulant material can be applied as a pre-formed layer or as a solution or dispersion using printing or patterning methods. A suitable hot melt adhesive containing a desiccant is DesiMax™ from Multisorb Technologies Inc. (Buffalo, N.Y.). A suitable encapsulant includes ethylene vinyl acetate or modified polyolefin thermoplastics such as 3M™ Thermo-bond (available from 3M of St. Paul, Minn.). The device may also be encapsulated in glass sheets as described in U.S. Pat. No. 6,355,125.

The one or more device layers 106 can be formed on the first electrode 104 by a variety of methods, e.g., coating (e.g., spin coating), printing (e.g., screen printing or ink jet printing), physical or chemical vapor deposition, and thermal transfer methods (e.g., methods described in U.S. Pat. No. 6,114,088). For example, the electrodes, light-emitting structure, and/or other optional layers may be formed by transferring one or more layers by laser thermal patterning. For example, the organic electroluminescent material can be coated on a donor sheet and then selectively transferred alone or in combination with other layers or with one or more electrodes to a receptor sheet. The receptor sheet can be pre-patterned with one or more electrodes, transistors, capacitors, insulator ribs, spacers, color filters, black matrix, hole transport layers, electron transport layers, other elements suitable for electronic displays and devices, or a combination thereof.

The one or more device layers 106 can be formed sequentially or two or more of the layers can be disposed simultaneously on the first electrode 104 or previously disposed device layers. After formation of the one or more device layers 106 or simultaneously with deposition of the device layers, the second electrode 108 is formed or otherwise disposed on the one or more device layers 106.

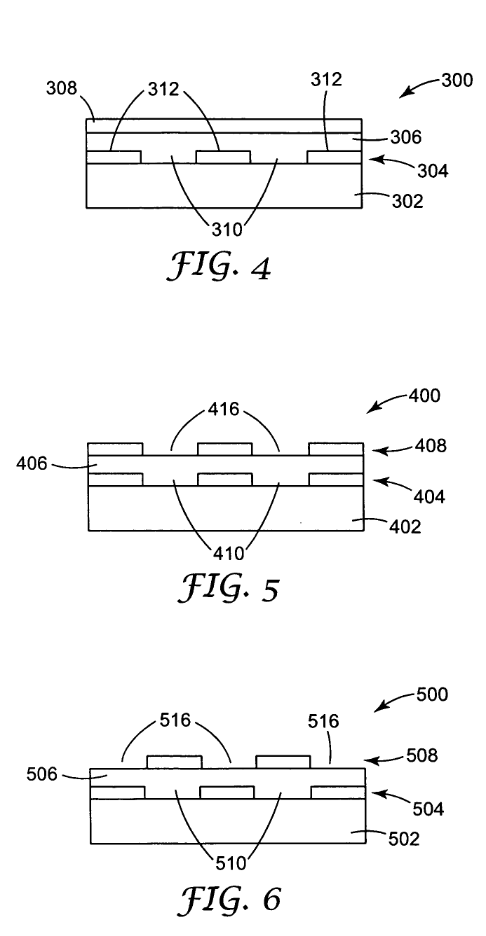

FIG. 4 illustrates another embodiment of an electroluminescent device 300 in which first electrode 304, instead of second electrode 308, defines apertures 310. This device 300 also includes one or more device layers 306, as described herein, and a substrate 302. In this embodiment, the substrate 302 is typically transparent to allow light to be emitted through the apertures 310 and transmitted through the substrate 302. All of the design considerations and possibilities described herein with respect to the second electrode 108 of the embodiment illustrated in FIGS. 1 and 2 apply equally to the first electrode 304 of the embodiment illustrated in FIG. 4.

In some embodiments, an optional planarization layer (not shown) can be formed within the apertures 310 after formation of the patterned first electrode 304. The planarization layer can have a thickness equal to, less than, or greater than the first electrode 304. The planarization layer can facilitate subsequent formation of device layers over the first electrode 304, if desired. However, in at least some instances, a planarization layer is not needed or desired. In at least some instances, one or more of the device layers can act as a planarization layer.

FIGS. 5 and 6 illustrate two embodiments of electroluminescent devices 400, 500 with first electrodes 404, 504 defining first apertures 410, 510 and second electrodes 408, 508 defining second apertures 416, 516. These embodiments also include a substrate 402, 502 and one or more device layers 406, 506.

In the embodiment illustrated in FIG. 5, the first and second apertures 410, 416 overlap. In some embodiments, the first and second apertures 410, 416 can be the same size and shape and are positioned over each other, as illustrated in FIG. 5. In other embodiments, the first and second apertures 410, 416 may only partially overlap due to differences in size, shape, position, or any combination thereof.

For example, FIG. 6 illustrates an embodiment where the first and second apertures 510, 516 do not completely overlap. In such embodiments, the first and second electrodes 504, 508 preferably overlap at least partially, as illustrated in FIG. 6. When the first and second electrodes 504, 508 are both opaque, then an electroluminescent device 500, as illustrated in FIG. 6, is capable of emitting light from both opposing sides of the device 500 while being opaque to transmission of light through the device 500. Such a device 500 may be used in any suitable type of apparatus, e.g., as a light source for illuminating rooms.

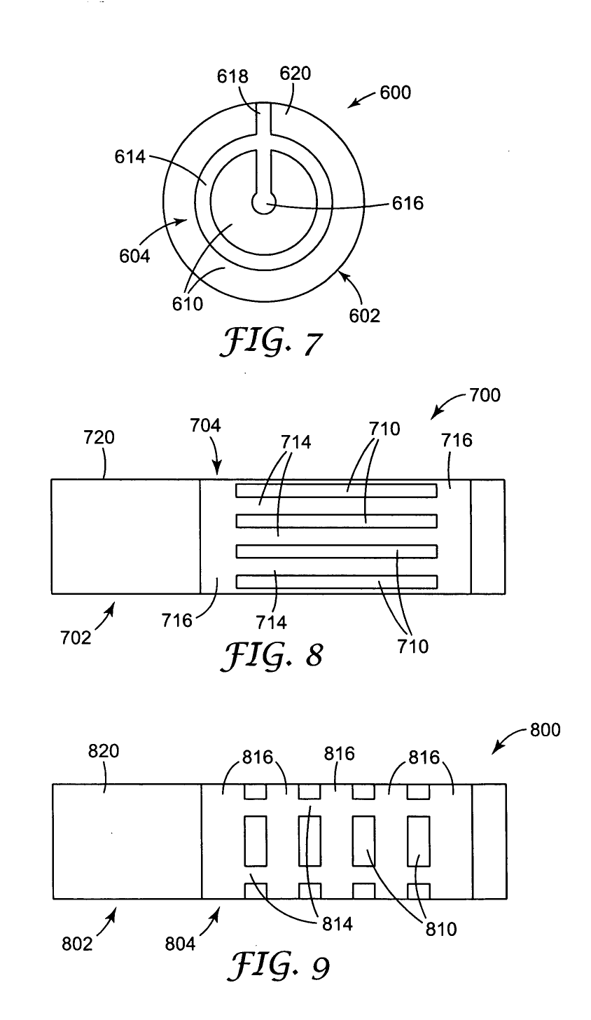

An electroluminescent device can also be coupled to or formed on an optical fiber or other media. FIGS. 7-9 illustrate embodiments of an electroluminescent device formed on a cylindrical surface, such as an optical fiber. FIG. 7 illustrates an end-coupled electroluminescent device 600 disposed on an end 620 of a cylindrical substrate 602. As used herein, the term “end-coupled electroluminescent device” is defined as a device where light is coupled to an end of a substrate, e.g., optical fiber. The electroluminescent device 600 includes a patterned first electrode 604 with one or more apertures 610. One or more device layers (not shown) and a second electrode (not shown), which can be patterned or unpatterned, are disposed on the end 620 of the cylindrical substrate 602 over first electrode 604. In the embodiment illustrated in FIG. 7, the first electrode 604 is patterned as an annular ring 614 and a center region 616 with a line 618 coupling the ring 614 and center region 616 and also, optionally, available for coupling to a voltage or current source. It will be recognized that other configurations can be selected, for example, a ring without a center region or an electrode substantially covering the entire end of the cylindrical substrate 602 with apertures formed through the electrode. The apertures 610 include the spaces between the ring 614 and center region 616 and optionally the regions outside the ring 614.

FIG. 8 illustrates one embodiment of electroluminescent device 700 formed on the curved surface 720 of a cylindrical substrate 702. The electroluminescent device 700 can be formed near an end of the cylindrical substrate 702 or at any other position along the cylindrical substrate 702. The electroluminescent device 700 includes a patterned first electrode 704 that defines the associated apertures 710, disposed on the cylindrical substrate 702 with one or more device layers (not shown) and a second electrode (not shown) disposed over the first electrode 704. The embodiment of FIG. 8 illustrates a patterned first electrode 704 with lines 714 running between two concentric rings 716. The apertures 710 include the regions between the lines 714 and optionally the regions outside the rings 716.

FIG. 9 illustrates another embodiment of an electroluminescent device 800 according to the present disclosure. Electroluminescent device 800 is similar in many respects to electroluminescent device 700 illustrated in FIG. 8. One difference between the two devices 700 and 800 is that electroluminescent device 800 includes a patterned first electrode 804 with several concentric rings 816 connected by one of more lines 814 running between the rings 816 to provide electrical connection. The apertures 810 include the regions between the rings 816 and optionally outside the outer rings. It will be recognized that many other electrode variations are possible, including, for example, a modified version of the embodiment of FIG. 7 with the lines extending from only a single ring, or a modified version of the embodiment of FIG. 9 with a single line connecting all of the concentric rings.

All references and publications cited herein are expressly incorporated herein by reference in their entirety into this disclosure. Illustrative embodiments of this disclosure are discussed and reference has been made to possible variations within the scope of this disclosure. These and other variations and modifications in the disclosure will be apparent to those skilled in the art without departing from the scope of the disclosure, and it should be understood that this disclosure is not limited to the illustrative embodiments set forth herein. Accordingly, the disclosure is to be limited only by the claims provided below.

1. An electroluminescent device, comprising:
a first electrode defining a plurality of apertures through the first electrode;
a second electrode defining a plurality of apertures through the second electrode, wherein the second electrode is opaque; and
a light emitting layer between the apertures in the first electrode and the apertures in the second electrode;
wherein the electroluminescent device is configured and arranged to emit light through the apertures in the first electrode and the second electrode when light is generated by the light emitting layer.

2. The electroluminescent device of claim 1, wherein the first electrode is opaque.

3. The electroluminescent device of claim 1, wherein the apertures through the first electrode are offset from the apertures through the second electrode.

4. The electroluminescent device of claim 3, wherein the apertures through the first electrode do not overlap the apertures through the second electrode.

5. The electroluminescent device of claim 1, wherein the electroluminescent device further comprises a substrate, and further wherein the first electrode is disposed on the substrate.

6. The electroluminescent device of claim 5, wherein the substrate is transparent.

7. The electroluminescent device of claim 1, wherein the electroluminescent device further comprises a substrate, and further wherein the second electrode is disposed on the substrate.

8. A method of emitting light, the method comprising:
providing an electroluminescent device comprising:
a first electrode defining a plurality of apertures through the first electrode;
a second electrode defining a plurality of apertures through the second electrode; and
a substantially flat light emitting layer extending laterally between the first electrode and second electrode and between the apertures in the first electrode and the apertures in the second electrode; and
applying an electrical signal to the first and second electrodes to cause the light emitting layer to emit light through the apertures in the first electrode and the apertures in the second electrode.

9. An electroluminescent device, comprising:
a first electrode;
a second electrode defining a plurality of apertures through the second electrode, wherein each aperture comprises an edge; and
a light emitting layer between the first electrode and the apertures in the second electrode;
wherein the electroluminescent device is configured and arranged to emit light through the apertures in the second electrode when light is generated by the light emitting layer, and further wherein the electroluminescent device is configured and arranged to provide an increased electric field strength proximate the edge of at least one aperture of the plurality of apertures.

10. The electroluminescent device of claim 9, wherein the second electrode is opaque.

11. The electroluminescent device of claim 9, wherein the first electrode defines a plurality of apertures through the first electrode.

12. The electroluminescent device of claim 11, wherein the first electrode is opaque.

13. The electroluminescent device of claim 11, wherein the apertures through the first electrode are offset from the apertures through the second electrode.

14. The electroluminescent device of claim 13, wherein the apertures through the first electrode do not overlap the apertures through the second electrode.

15. The electroluminescent device of claim 9, wherein the electroluminescent device further comprises a substrate, and further wherein the first electrode is disposed on the substrate.

16. The electroluminescent device of claim 9, wherein the electroluminescent device further comprises a cylindrical substrate.

17. The electroluminescent device of claim 16, wherein the cylindrical substrate comprises an optical fiber.

18. The electroluminescent device of claim 16, wherein the first and second electrodes are at least partially disposed around a curved surface of the cylindrical substrate.

19. The electroluminescent device of claim 16, wherein the first and second electrodes are disposed on an end of the cylindrical substrate.

20. The electroluminescent device of claim 9, wherein the device is further configured and arranged to provide an increased electric field gradient proximate the edge of at least one aperture of the plurality of apertures.
